(19) United States
(12) Patent Application Publication
(10) Pub. No.: US 2013/0087094 A1
(43) Pub. Date: Apr. 11, 2013

(54) Composite Crucible For Crystal Growth

(71) Applicants: Brant Quinton, Knoxville, TN (US); Troy Marlar, Knoxville, TN (US)

(72) Inventors: Brant Quinton, Knoxville, TN (US); Troy Marlar, Knoxville, TN (US)

(73) Assignee: SIEMENS MEDICAL SOLUTIONS USA, INC., Malvern, PA (US)

(21) Appl. No.: 13/305,803

(22) Filed: Nov. 29, 2011

Related U.S. Application Data
(60) Provisional application No. 61/543,334, filed on Oct. 5, 2011.

(51) Int. Cl. C30B 15/10; B23K 31/02

(52) U.S. Cl. 117/208; 228/173.6

(57) ABSTRACT

A composite crucible comprising an iridium alloy sidewall and an iridium bottom. The iridium alloy is selected from the group consisting of iridium, rhenium, rhodium and tungsten. In some embodiments the iridium alloy comprises about 99 to 95 parts iridium and about 1 to 5 five parts rhenium. The crucible can be fabricated by rolling a flat sheet of iridium alloy into a cylinder and affixing an iridium circular bottom to one end of the cylinder. Seams can be welded to complete the composite crucible structure.

### CLAIM TO PRIORITY

This application claims the benefit of co-pending United States provisional patent application entitled “Reinforced Crucible Design” filed Oct. 5, 2011 and assigned Ser. No. 61/543,334, which is incorporated by reference herein.

### BACKGROUND OF THE DISCLOSURE

1. Field of the Invention

The invention relates to crucibles for crystal growth, and more particularly crucibles for growing crystals by the Czochralski technique using an iridium crucible to contain a crystal melt.

2. Description of the Prior Art

The Czochralski technique is used in the electronics industry to grow single crystals. The crystals may be used, for example, in detectors for positron emission tomography (PET) medical scanners. Generally, the Czochralski technique grows a single crystal by withdrawing a rotating crystal seed from contact with a molten bath that is contained within a heated crucible. The crucible is often heated with a radio-frequency energy-emitting coil. As the crystal is withdrawn from the crucible the melt solidifies on the seed. Ultimate crystal diameter is controlled, among other ways, by the withdrawal rate from the melt and the heat application.

FIG. 1 shows a conventional crucible 10, having a cylindrical sidewall 12 and a bottom 14. In the past the crucible sidewall 12 has been cast or sintered from pure iridium, or alternatively formed from a rolled flat sheet of iridium with a welded butt-seam. Thereafter an iridium bottom 14 was welded to the sidewall 12. Both the bottom 14 and sidewall 12 were constructed of the same iridium material. Some known crucibles were sintered or cast as a unified iridium structure.

When a conventional crucible 10 (whether cast, sintered or fabricated from sheet) is used in a crystal growth cycle, residual melt material remains in the bottom of the crucible after growth of a crystal boule. As the crucible cools during furnace power-down cycle, the residual melt material hardens and expands radially. Over the course of subsequent growth cycles the crucible 10 sidewall 12 tends to bulge radially outwardly, as shown in FIG. 2. As the sidewall 12 bulge increases during subsequent cycles the hardened crystal melt must be mechanically or chemically stripped from the sidewall. The sidewall bulge can be reduced in diameter by attempting to re-roll the crucible to its original straight sidewall profile, but due to stretching of the bottom material the original diameter cannot be restored. Ultimately the bulged crucible 10 is scrapped and replaced.

In the past iridium alloys were adopted to increase crucible hardness and mechanical resistance to radial bulging during crystal growth cycles by constructing an entire crucible from the same alloy material. Exemplary alloys included iridium-tungsten, iridium-rhenium and iridium-rhodium. U.S. Pat. No. 4,444,728 describes a crucible for single crystal growth comprised of from about 80 to 99 parts of iridium and from about 1 to about 20 parts of rhenium. Such iridium alloys resist radial expansion during repetitive crystal growth cycles, but have a higher propensity to develop cracks on the crucible bottom than those that are constructed of iridium alone. As cracked crucibles risk loss of high temperature molten material during a crystal growth cycle, conservative maintenance schedules mandate alloy crucible scrapping and replacement before observation of thermally induced cracks in the bottom structure.

Thus in the past, a crystal growth foundry had to choose whether to use iridium crucibles, with propensity to bulge during multiple crystal fabrication cycles, or use iridium alloy crucibles with potentially longer life and less need to re-profile sidewalls, but with greater propensity to develop brittle cracks.

Thus, a need exists in the art for a crystal growth crucible that resists sidewall bulging during crystal growth cycles without increasing susceptibility to develop cracks after repetitive cycles.

### SUMMARY OF THE INVENTION

Accordingly, an object of the present invention is to create a crystal growth crucible that resists sidewall bulging deformation after multiple crystal growth cycles.

Another object of the present invention is to create a crystal growth crucible that resists bottom cracking after multiple crystal growth cycles.

Another object of the present invention is to create a crystal growth crucible that resists sidewall bulging deformation and bottom cracking after multiple crystal growth cycles, using fabrication techniques and materials familiar to those skilled in the art.

These and other objects are achieved in accordance with an embodiment of the present invention by a composite crucible comprising an iridium alloy sidewall and an iridium bottom. In some embodiments the iridium alloy comprises about 99 to 95 parts iridium and about 1 to 5 five parts rhenium.

An embodiment of the present invention features a composite crystal growth crucible comprising an iridium alloy sidewall and an iridium bottom. In some embodiments the iridium alloy comprises iridium and rhenium. In some embodiments the iridium alloy comprises about 99 to 95 parts iridium and about 1 to 5 five parts rhenium. In some embodiments the iridium alloy comprises iridium combined with rhodium or tungsten. In some embodiments the crucible has a cylindrical sidewall and flat circular bottom prior to initial use. In some embodiments the bottom is welded to the sidewall. In some embodiments the bottom and sidewall have the same outer diameter and the sidewall abuts a surface of the bottom that defines a crucible interior. Yet in other embodiments the bottom has a peripheral edge that abuts an inner surface of the sidewall that defines a crucible interior. The crucible may have: a diameter between approximately 152 mm (6 inches) and 254 mm (10 inches); a height between approximately 152 mm (6 inches) to 356 mm (14 inches); and bottom and sidewall thicknesses between approximately 2.5 mm (0.1 inch) and 5 mm (0.2 inch) prior to initial use.

An embodiment of the present invention also features a composite crystal growth crucible comprising an iridium alloy sidewall formed by rolling and welding a rectangular-shaped sheet of iridium alloy into a cylinder; and welding an iridium circular-shaped bottom to one end of the sidewall. In some embodiments the iridium alloy comprises iridium and rhenium. In some embodiments the iridium alloy comprises about 99 to 95 parts iridium and about 1 to 5 five parts rhenium. In some embodiments the iridium alloy comprises iridium in combination with rhodium or tungsten. In some embodiments the bottom and sidewall have the same outer diameter and the sidewall abuts a surface of the bottom that defines a crucible interior. In other embodiments the bottom has a peripheral edge that abuts an inner surface of the sidewall that defines a crucible interior. In some embodiments the crucible has: a diameter between approximately 6 inches (152 mm) and 10 inches (254 mm); a height between approximately 6 inches (152 mm) to 14 (356 mm) inches; and the bottom and sidewall respectively have thicknesses between approximately 0.1 inch and 0.2 inch prior to initial use.

An embodiment of the present invention also features a method for fabricating a composite crystal growth crucible comprising: forming an iridium alloy sidewall and affixing an iridium bottom to one end of the sidewall. In some embodiments the sidewall formation step further comprises rolling and welding a rectangular-shaped sheet of iridium alloy into a cylinder; and the bottom affixing step further comprises welding an iridium circular-shaped bottom to one end of the sidewall. In some embodiments the iridium alloy comprises about 99 to 95 parts iridium and about 1 to 5 five parts rhenium. In some embodiments the iridium alloy comprises rhodium or tungsten.

The objects and features of embodiments of the present invention may be applied jointly or severally in any combination or sub-combination by those skilled in the art.

### BRIEF DESCRIPTION OF THE DRAWINGS

The teachings of embodiments of the present invention can be readily understood by considering the following detailed description in conjunction with the accompanying drawings, in which:

FIG. 1 is a perspective view of a prior art crucible before initial use in a crystal growth furnace;

FIG. 2 is a perspective view of the prior art crucible after repeated use in a crystal growth furnace;

FIG. 3 is a perspective view of an embodiment of the composite crucible of the present invention;

FIG. 4 is a perspective view of another embodiment of the composite crucible of the present invention;

FIG. 5 is a plan view of respective crucible sidewall and bottom components used to fabricate a composite crucible of an embodiment of the present invention; and

FIG. 6 is an exploded perspective view of a crucible of an embodiment of the present invention, formed from the components of FIG. 5.

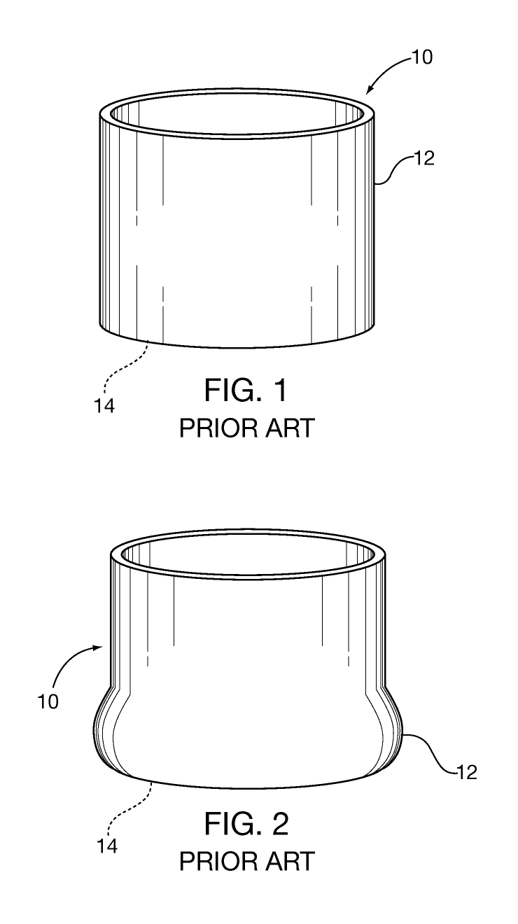

To facilitate understanding, identical reference numerals have been used, where possible, to designate identical elements that are common to the figures.

### DETAILED DESCRIPTION

After considering the following description, those skilled in the art will clearly realize that the teachings of embodiments of the present invention can be readily utilized in a composite crucible comprising an iridium alloy sidewall and an iridium bottom. The composite crucible structure resists both sidewall bulging and bottom cracking better than known crucibles formed solely from either iridium or iridium alloys.

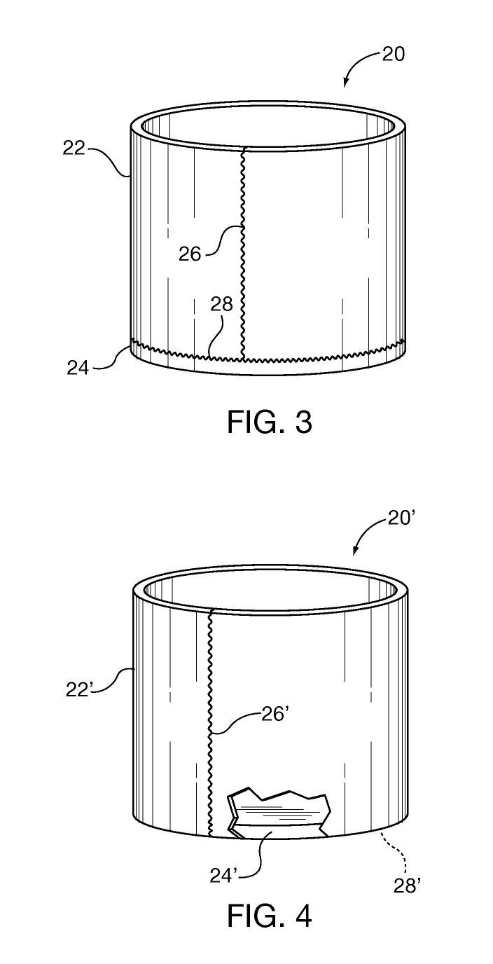

In FIG. 3 one embodiment of the composite crucible 20 of the present invention has a cylindrical profile sidewall 22 that is joined to a circular bottom 24 that has the same outer diameter as the sidewall. One end of the cylindrical sidewall 22 rests on top of a surface of the bottom 24. Seams are joined by welding, as indicated schematically by the undulating lines 26 and 28. The weld beads 26, 28 are formed using known welding techniques, such as for example tungsten inert gas welding using filler rod material that is compatible with iridium and iridium alloys.

FIG. 4 shows another embodiment of a crucible 20′ of the present invention, wherein the sidewall 22′ captures the bottom 24′ therein, so that a peripheral edge of the bottom abuts against the interior inner diameter of the sidewall cylinder. Seams 26′ and 28′ are joined by weld beads.

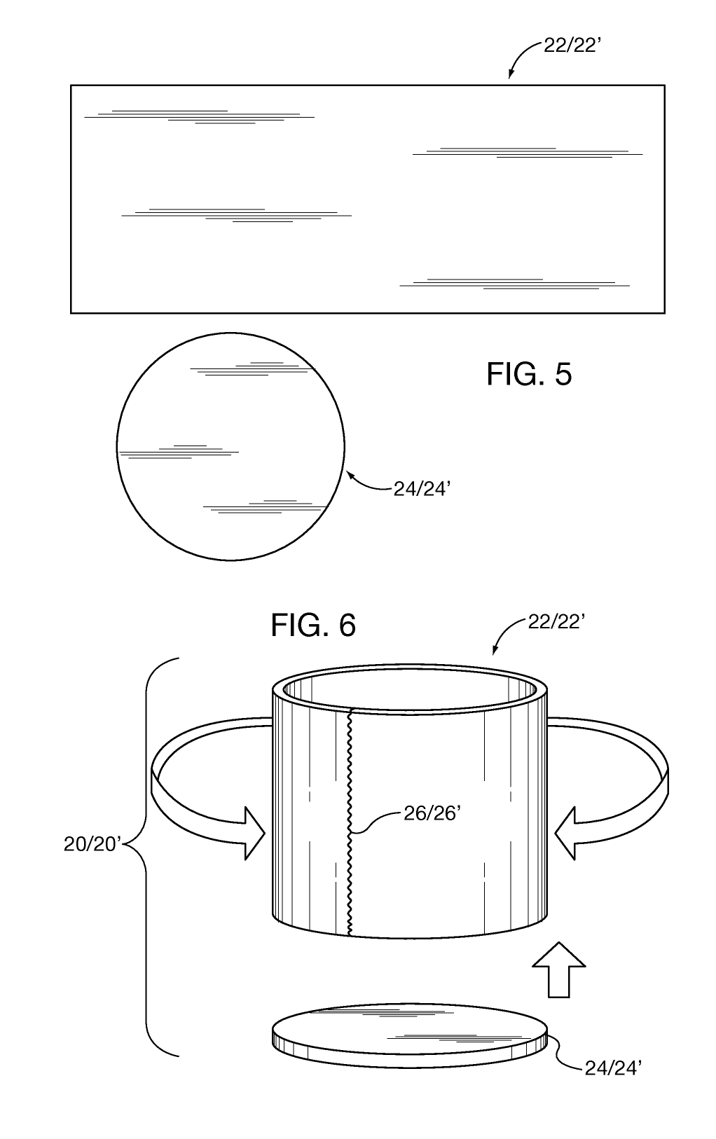

FIGS. 5 and 6 show an exemplary method for fabricating a composite crucible 20, 20′ in accordance with an embodiment of the present invention by forming a rectangular sheet of iridium alloy 22/22′ and rolling it into an annular, open-ended cylinder. The crucible bottom 24/24′ is formed from a circular flat sheet. The crucible sidewall 22/22′ is affixed to the bottom 24/24′ and all seams are joined by weld beads 26/26′ and 28/28′ (the latter weld bead not being shown in these figures. While the exemplary embodiment of FIGS. 5 and 6 are fabricated from welded sheet material the sidewall 22/22′ can be fabricated from seamless tubular stock, or otherwise formed by a casting or sintering process, without the side seam 26/26′. Similarly the entire crucible 20 of the present invention can be formed by a unitized casting or sintering process whereby the bottom portion 24 is formed from an iridium material and the sidewall portion 22 is formed from an iridium alloy.

Typically a composite crucible of an embodiment of the present invention is constructed with a cylindrical diameter between approximately 152 mm (6 inches) and 254 mm (10 inches) and a height between approximately 152 mm (6 inches) to 356 mm (14 inches). The bottom and sidewall respectively have thicknesses between approximately 2.5 mm (0.1 inch) and 5 mm (0.2 inch) prior to initial use. After initial use thermal cycling experienced during the process will cause some measure of distortion of the initial fabrication dimensions.

The iridium alloys used for construction of the crucible sidewall comprise combinations of iridium and any of rhenium, rhodium and tungsten. A suitable iridium alloy comprises about 99 to 95 parts iridium and about 1 to 5 five parts rhenium.

Although various embodiments which incorporate the teachings of the present invention have been shown and described in detail herein, those skilled in the art can readily devise many other varied embodiments that still incorporate these teachings. For example, while crystal growth crucibles traditionally have been constructed in a cylindrical shape, crucibles of the present invention can be constructed in other desired shapes, with the bottom being constructed of iridium and the sidewall being constructed from an iridium alloy.

What is claimed is:

1. A composite crystal growth crucible comprising: an iridium alloy sidewall and an iridium bottom.

2. The crucible of claim 1, wherein the iridium alloy is selected from the group consisting of iridium, rhenium, rhodium and tungsten.

3. The crucible of claim 2, wherein the iridium alloy comprises about 99 to 95 parts iridium and about 1 to 5 five parts rhenium.

4. The crucible of claim 1, having a cylindrical sidewall and flat circular bottom prior to initial use.

5. The crucible of claim 4, wherein the bottom is welded to the sidewall.

6. The crucible of claim 5, wherein the bottom and sidewall have the same outer diameter and the sidewall abuts a surface of the bottom that defines a crucible interior.

7. The crucible of claim 5, wherein the bottom has a peripheral edge that abuts an inner surface of the sidewall that defines a crucible interior.

8. The crucible of claim 4, having a diameter between approximately 6 inches and 10 inches, and a height between approximately 6 inches to 14 inches.

9. The crucible of claim 4, wherein the bottom and sidewall respectively have thicknesses between approximately 0.1 inch and 0.2 inch prior to initial use.

10. A composite crystal growth crucible comprising: an iridium alloy sidewall formed by rolling and welding a rectangular-shaped sheet of iridium alloy into a cylinder; and welding an iridium circular-shaped bottom to one end of the sidewall.

11. The crucible of claim 10, wherein the iridium alloy is selected from the group consisting of iridium, rhenium, rhodium and tungsten.

12. The crucible of claim 10, wherein the iridium alloy comprises about 99 to 95 parts iridium and about 1 to 5 five parts rhenium.

13. The crucible of claim 10, wherein the bottom and sidewall have the same outer diameter and the sidewall abuts a surface of the bottom that defines a crucible interior.

14. The crucible of claim 10, wherein the bottom has a peripheral edge that abuts an inner surface of the sidewall that defines a crucible interior.

15. The crucible of claim 10, having a diameter between approximately 6 inches and 10 inches, and a height between approximately 6 inches to 14 inches.

16. The crucible of claim 10, wherein the bottom and sidewall respectively have thicknesses between approximately 0.1 inch and 0.2 inch prior to initial use.

17. A method for fabricating a composite crystal growth crucible comprising:
forming an iridium alloy sidewall; and
affixing an iridium bottom to one end of the sidewall.

18. The method of claim 17, wherein:
the sidewall formation step further comprises rolling and welding a rectangular-shaped sheet of iridium alloy into a cylinder; and
the bottom affixing step further comprises welding an iridium circular-shaped bottom to one end of the sidewall.

19. The method of claim 17, wherein the iridium alloy wherein the iridium alloy is selected from the group consisting of iridium, rhenium, rhodium and tungsten.

20. The method of claim 19, wherein iridium alloy comprises about 99 to 95 parts iridium and about 1 to 5 five parts rhenium.
